(19) United States
(12) Patent Application Publication
(10) Pub. No.: US 2019/0013441 A1
(43) Pub. Date: Jan. 10, 2019

(54) LIGHT-EMITTING ELEMENT

(71) Applicant: LG INNOTEK CO., LTD., Seoul (KR)

(72) Inventors: Jun Hee HONG, Seoul (KR); Jae Won SEO, Seoul (KR)

(73) Assignee: LG INNOTEK CO., LTD., Seoul (KR)

(21) Appl. No.: 16/066,511

(22) PCT Filed: Dec. 26, 2016
(86) PCT No.: PCT/KR2016/015253

§ 371 Date: Jun. 27, 2018

(30) Foreign Application Priority Data
Dec. 28, 2015 (KR) 10-2015-0187457

(51) Int. Cl. H01L 33/38; H01L 33/24; H01L 33/44; H01L 33/46; H01L 33/42; H01L 33/62; H01L 33/14; H01L 33/40

(52) U.S. Cl. CPC H01L 33/382; H01L 33/24; H01L 33/44; H01L 33/46; H01L 33/32; H01L 33/62; H01L 33/14; H01L 33/405; H01L 33/42

(57) ABSTRACT

Exemplary embodiments relate to a light-emitting element capable of facilitating current spreading and improving a driving voltage by increasing a connection area between a first electrode and a first semiconductor layer. The light-emitting element includes: a light-emitting structure including a first semiconductor layer, an active layer, and a second semiconductor layer; a groove configured to expose the first semiconductor layer at a bottom surface thereof and expose the first semiconductor layer, the active layer, and the second semiconductor layer at side surfaces thereof due to the light-emitting structure being removed; a first electrode connected to the first semiconductor layer exposed at the bottom surface of the groove; a first insulating pattern configured to cover the first semiconductor layer, the active layer, and the second semiconductor layer which are exposed at the side surfaces of the groove, wherein one end thereof extends to a portion of an upper surface of the first electrode and the other end thereof extends to a portion of an upper surface of the second semiconductor layer such that the upper surfaces of the first electrode and the second semiconductor layer are partially exposed; a first reflective layer disposed on the exposed second semiconductor layer; a second reflective layer configured to expose the second semiconductor layer and the first electrode; and a second electrode disposed on the second semiconductor layer exposed by the second reflective layer.

### TECHNICAL FIELD

Exemplary embodiments of the present invention relate to a light-emitting element in which current spreading and a driving voltage are improved.

### BACKGROUND ART

A light emitting diode (LED) is one light-emitting element which is configured to emit light when a current is applied thereto. Since the LED may emit high efficient light using a low voltage, the LED has an excellent energy-saving effect. Recently, a brightness problem of the LED has been greatly improved, and thus, the LED has been applied to various devices such as a backlight unit of liquid crystal displays, electric signboards, indicators, and home appliances.

An LED may have a structure in which a first electrode and a second electrode are disposed at one side of a light-emitting structure including a first semiconductor layer, an active layer, and a second semiconductor layer.

In the case of a vertical LED, a first electrode may be electrically connected to a first semiconductor layer through a groove passing through the first semiconductor layer, an active layer, and a second semiconductor layer. In order for a first bonding pad which is connected to a first electrode, which will be described later, to be prevented from being connected with an active layer and a second semiconductor layer exposed in a groove, a general vertical LED further includes a first insulating pattern configured to cover the active layer and the second semiconductor layer exposed in the groove.

A contact area between the first electrode and the first semiconductor layer is very small compared to a contact area between the second electrode and the second semiconductor layer. As a result, a current crowding phenomenon occurs in a contact region between the first electrode and the first semiconductor layer. Thus, heat generation is increased around the first electrode, and concurrently, a driving voltage is also increased.

In order to increase the contact area between the first electrode and the first semiconductor layer, there is a method of narrowing a distance between the first electrode and the insulating pattern or there is a method of widely forming the first electrode. However, when the first electrode and the first insulating pattern are too close to each other, reflection efficiency of a reflection layer to be forming on the insulating pattern may be reduced. In addition, due to a process margin of the first electrode and the first insulating pattern, the first electrode may completely cover the first insulating pattern. Furthermore, when a groove having a wide bottom surface is formed to widely form the first electrode, an area of the active layer of a light-emitting structure is reduced. Therefore, luminous efficiency may be reduced.

That is, since a general light-emitting element has a limitation in widening a width of a first electrode, it is difficult to increase a contact area between the first electrode and a first semiconductor layer.

### Technical Solution

The present invention is directed to providing a light-emitting element capable of facilitating current spreading and improving a driving voltage by increasing a connection area between a first electrode and a first semiconductor layer without increasing a size of a groove.

A light-emitting element according to an exemplary embodiment of the present invention includes: a light-emitting structure including a first semiconductor layer, an active layer, and a second semiconductor layer; a groove configured to expose the first semiconductor layer at a bottom surface thereof and expose the first semiconductor layer, the active layer, and the second semiconductor layer at side surfaces thereof due to the light-emitting structure being removed; a first electrode connected to the first semiconductor layer exposed at the bottom surface of the groove; a first insulating pattern configured to cover the first semiconductor layer, the active layer, and the second semiconductor layer which are exposed at the side surfaces of the groove, wherein one end thereof extends to a portion of an upper surface of the first electrode and the other end thereof extends to a portion of an upper surface of the second semiconductor layer such that the upper surfaces of the first electrode and the second semiconductor layer are partially exposed; a first reflective layer disposed on the exposed second semiconductor layer; a second reflective layer configured to expose the second semiconductor layer and the first electrode; and a second electrode disposed on the second semiconductor layer exposed by the second reflective layer.

A light-emitting element according to another exemplary embodiment of the present invention includes: a light-emitting structure including a first semiconductor layer, an active layer, and a second semiconductor layer; a groove configured to expose the first semiconductor layer at a bottom surface thereof and expose the first semiconductor layer, the active layer, and the second semiconductor layer at side surfaces thereof due to the light-emitting structure being removed; a first electrode connected to the first semiconductor layer exposed at the bottom surface of the groove; a first insulating pattern configured to cover the first semiconductor layer, the active layer, and the second semiconductor layer which are exposed at the side surfaces of the groove, wherein one end thereof extends to a portion of an upper surface of the first electrode and the other end thereof extends to a portion of an upper surface of the second semiconductor layer such that the upper surfaces of the first electrode and the second semiconductor layer are partially exposed; a first reflective layer disposed on the exposed second semiconductor layer; a second insulating pattern configured to cover the first reflective layer and expose the second semiconductor layer and the first electrode; a second reflective layer disposed on the second insulating pattern and configured to expose the second semiconductor layer and the first electrode; and a second electrode disposed on the second semiconductor layer exposed by the second insulating pattern and the second reflective layer.

### Advantageous Effects

A light-emitting element according to an exemplary embodiment of the present invention has the following effects.

First, a connection area between a first electrode and a first semiconductor layer can be increased without additionally removing an active layer. Accordingly, a driving voltage can be improved, current spreading of a light-emitting structure can be facilitated, and the driving voltage may be reduced.

Second, a second insulating pattern can be disposed between a first insulating pattern and a second reflective layer, thereby compensating for a bent degree of the second reflective layer between a side surface of a groove and an edge of the first electrode.

Third, the second reflective layer can be disposed to cover the side surface of the groove and to easily reflect light traveling to the side surface of the groove toward a light emission surface of a light-emitting structure, thereby improving a luminous flux of the light-emitting element.

### DESCRIPTION OF DRAWINGS

FIG. 1 is a plan view illustrating a light-emitting element according to an exemplary embodiment of the present invention.

FIG. 2A is a cross-sectional view taken along line IT of FIG. 1.

FIG. 2B is an enlarged view of region A of FIG. 2A.

FIG. 3 is a cross-sectional view illustrating a connection region between a general first electrode and a general first semiconductor layer.

FIG. 4A is a cross-sectional view taken along line IT of FIG. 1, according to another exemplary embodiment.

FIG. 4B is an enlarged view of region A of FIG. 4A.

### MODES OF THE INVENTION

While the present invention is open to various modifications and alternative embodiments, specific embodiments thereof will be described and shown by way of example in the drawings. However, it should be understood that there is no intention to limit the present invention to the particular embodiments disclosed, and, on the contrary, the present invention is to cover all modifications, equivalents, and alternatives falling within the spirit and scope of the present invention.

It should be understood that, although the terms including ordinal numbers such as “first,” “second,” and the like may be used herein to describe various elements, the elements are not limited by the terms. The terms are only used to distinguish one element from another. For example, a second element could be termed a first element without departing from the scope of the present invention, and similarly a first element could be also termed a second element. The term “and/or” includes any and all combinations of a plurality of associated listed items.

In case one component is mentioned as “connected to” or “accessing” another component, it may be connected to or access the corresponding component directly. However, other component(s) may exist in between. On the other hand, in case that one component is mentioned as “directly connected to” or “directly accessing” another component, it should be understood that other component(s) may not exist in between.

The terminology used herein is for the purpose of describing particular embodiments only and is not intended to limit the present invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components, and/or groups thereof but do not preclude the presence or addition of one or more other features, integers, steps, operations, elements, components, and/or groups thereof.

Unless defined otherwise, all the terms (including technical and scientific terms) used herein have the same meaning as commonly understood by one of ordinary skill in the art to which the present invention belongs. It will be further understood that the terms, such as those defined in commonly used dictionaries, should be interpreted as having meanings that are consistent with their meanings in the context of the relevant art, and should not be interpreted in an idealized or overly formal sense unless expressly defined otherwise herein.

Hereinafter, example embodiments will be described in detail with reference to the attached drawings, and the same or corresponding elements will be given the same reference numbers regardless of drawing symbols, and redundant descriptions will be omitted.

Hereinafter, a light-emitting element according to an exemplary embodiment will be described in detail with reference to the accompanying drawings.

### First Exemplary Embodiment

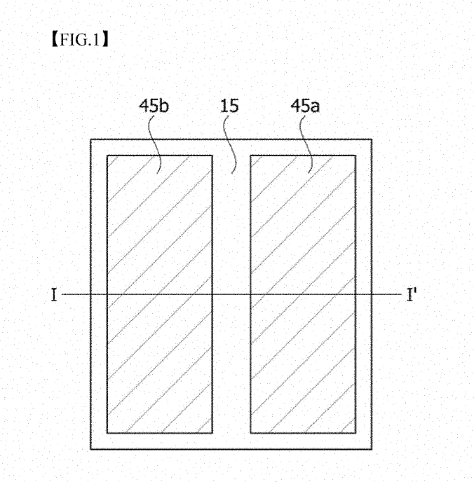

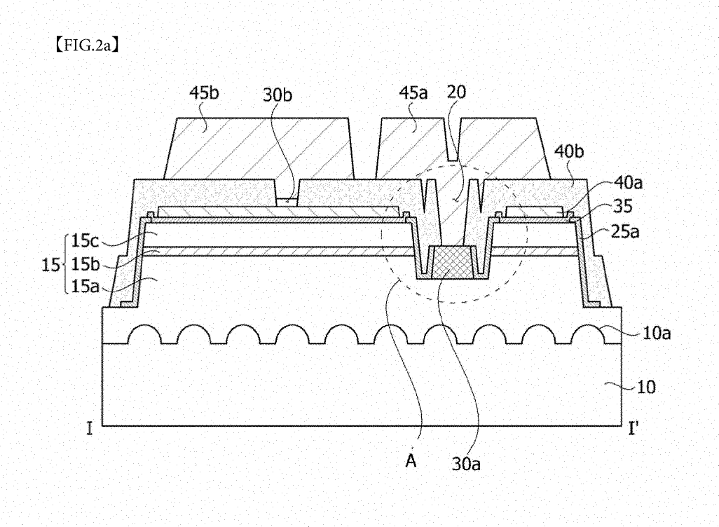

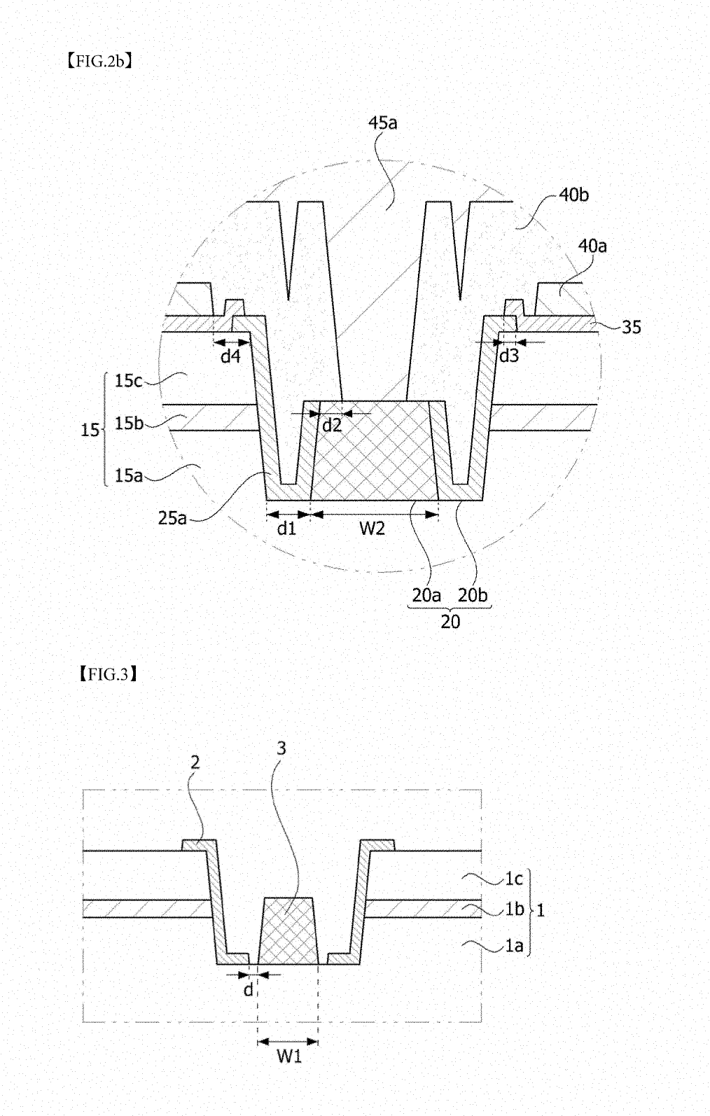

FIG. 1 is a plan view illustrating a light-emitting element according to an exemplary embodiment of the present invention. FIG. 2A is a cross-sectional view taken along line I-I′ of FIG. 1, and FIG. 2B is an enlarged view of region A of FIG. 2A.

As shown in FIGS. 1, 2A, and 2B, the light-emitting element according to the exemplary embodiment of the present invention includes a light-emitting structure 15 including a first semiconductor layer 15a, an active layer 15b, and a second semiconductor layer 15c; a groove 20 configured to expose the first semiconductor layer 15a at a bottom surface 20a thereof and expose the first semiconductor layer 15a, the active layer 15b, and the second semiconductor layer 15c at side surfaces 20b thereof due to the light-emitting structure 15 being removed; a first electrode 30a connected to the first semiconductor layer 15a exposed at the bottom surface 20a of the groove 20; a first insulating pattern 25a configured to cover the first semiconductor layer 15a, the active layer 15b, and the second semiconductor layer 15c exposed at the side surfaces 20b of the groove 20; a first reflective layer 40a disposed on the exposed second semiconductor layer 15c; a second reflective layer 40b configured to expose the first reflective layer 40a and the first electrode 30a; and a second electrode 30b disposed on the first reflective layer 40a exposed by the second reflective layer 40b, the first insulating pattern 25a having one end extending to a portion of an upper surface of the first electrode 30a and the other end extending to a portion of an upper surface of the second semiconductor layer 15c such that the upper surfaces of the first electrode 30a and the second semiconductor layer 15c are partially exposed.

A substrate 10 may include a conductive substrate or an insulating substrate. The substrate 10 may be made of a material suitable for growing a semiconductor material or may be a carrier wafer. The substrate 10 may be made of a material selected from sapphire (Al₂O₃), SiC, GaAs, GaN, ZnO, Si, GaP, InP, and Ge, but the present invention is not limited thereto. The substrate 10 may be removed.

Although not shown, a buffer layer (not shown) may be further disposed between the light-emitting structure 15 and the substrate 10. The buffer layer may attenuate a lattice mismatch between the first semiconductor layer 15a and the substrate 10. The buffer layer may have a form in which Group III elements are combined with Group V elements, or may include at least one selected from GaN, InN, AlN, InGaN, AlGaN, InAlGaN, and AlInN. The buffer layer may be doped with a dopant, but the present invention is not limited thereto. The buffer layer may be grown as a single crystal on the substrate 10 and may improve crystallinity of the first semiconductor layer 15a.

In particular, an uneven portion 10a may be formed at an interface between the light-emitting structure 15 and the substrate 10 so as to diffuse and emit light when the light generated in the light-emitting structure 15 is emitted to the outside through the substrate 10. The uneven portion 10a may have a regular shape, as shown, or an irregular shape, and a shape thereof may be easily changed.

The first semiconductor layer 15a may be implemented using a III-V group or II-IV group compound semiconductor or the like, and may be doped with a first dopant. The first semiconductor layer 15a may be made of at least one material selected from semiconductor materials having an empirical formula of Inₓ₁Al_{y1}Ga_{1-x1-y1}N (0≤x1≤1, 0≤y1≤1, and 0≤x1+y1≤1), such as GaN, AlGaN, InGaN, and InAlGaN. The first dopant may be an n-type dopant such as Si, Ge, Sn, Se, or Te. When the first dopant is the n-type dopant, the first semiconductor layer 15a doped with the first dopant may be an n-type semiconductor layer.

The active layer 15b is a layer in which electrons (or holes) injected through the first semiconductor layer 15a meet holes (or electrons) injected through the second semiconductor layer 15c. As electrons and holes are recombined and transition to a low energy level, the active layer 15b may generate light having a wavelength corresponding thereto.

The active layer 15b may have any one of a single well structure, a multi well structure, a single quantum well structure, a multi quantum well (MQW) structure, a quantum dot structure, and a quantum line structure, but a structure of the active layer 15b is not limited thereto.

The second semiconductor layer 15c may be formed on the active layer 15b, may be implemented using a III-V group or II-IV group compound semiconductor or the like, and may be doped with a second dopant. The second semiconductor layer 15c may be made of a semiconductor material having an empirical formula of Inₓ₂Al_{y2}Ga_{1-x2-y2}N (0≤x2≤1, 0≤y2≤1, and 0≤x2+y2≤1), or may be made of a material selected from AlInN, AlGaAs, GaP, GaAs, GaAsP, and AlGaInP. When the second dopant is a p-type dopant such as Mg, Zn, Ca, Sr, or Ba, the second semiconductor layer 15c doped with the second dopant may be a p-type semiconductor layer.

The first electrode 30a may be electrically connected to the first semiconductor layer 15a through the groove 20 formed by selectively removing the first semiconductor layer 15a, the active layer 15b, and the second semiconductor layer 15c. The first semiconductor layer 15a may be exposed at the bottom surface 20a of the groove 20, and the first semiconductor layer 15a, the active layer 15b, and the second semiconductor layer 15c may be exposed at the side surfaces 20b of the groove 20.

An entire lower surface of the first electrode 30a may be connected to the first semiconductor layer 15a. The first electrode 30a may be made of one selected from Ag, Ni, Al, Rh, Pd, Ir, Ru, Mg, Zn, Pt, Au, Hf, Ti, Cr, Cu, and a selective combination thereof, but the present invention is not limited thereto. Generally, aluminum (Al) has very high reflectance and very low reflectivity. Accordingly, when the first electrode 30a includes aluminum, light generated in the active layer 15b may travel to the first electrode 30a and may be reflected and emitted to the outside by the first electrode 30a without being absorbed by the first electrode 30a. In addition, contact resistance may be reduced between the first electrode 30a and the first semiconductor layer 15a.

However, since aluminum may diffuse at high temperatures, when the first electrode 30a is made of aluminum, it is desirable that the first electrode 30a further includes a barrier metal in order to prevent diffusion of aluminum. Here, the barrier metal may be selected from Ni, TiW, Pt, W, and the like. In this case, the first electrode 30a may have a structure selected from structures of Cr/Al/Ni, Cr/Al/TiW, Cr/Al/Pt, Cr/Al/W, and the like.

A distance between an edge of the first electrode 30a and an edge of the bottom surface 20a of the groove 20, i.e., a first distance d1 may be in a range of 0.05 μm to 8 μm. Desirably, the first distance d1 may be in a range of 3 μm to 5 μm. When the first distance d1 is narrow, the first electrode 30a may extend to the side surface 20b of the groove 20. Thus, the first electrode 30a may be connected to the active layer 15b or the second semiconductor layer 15c. In addition, when the first interval d1 is wide, a width W2 of the first electrode 30a may become too narrow.

In particular, when a diameter of the groove 20 is too large, a removed area of the active layer 15b may be increased, resulting in a reduction in an emission region. When the diameter of the groove 20 is too small, a driving voltage of the light-emitting element may be increased. That is, it is proper that the diameter of the groove 20 is generally in a range of 20 μm to 25 μm, and it may be difficult to adjust the diameter of the groove 20 so as to increase the width W2 of the first electrode 30a.

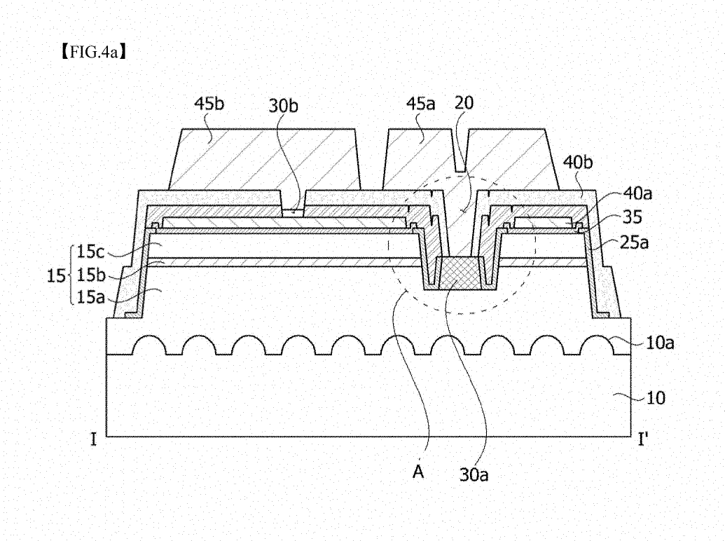

FIG. 3 is a cross-sectional view illustrating a connection region between a general first electrode and a general first semiconductor layer.

As shown in FIG. 3, in a general light-emitting element, a groove is formed in a light-emitting structure 1 so as to connect a first electrode 3 and a first semiconductor layer 1a. An insulating pattern 2 is formed to cover the first semiconductor layer 1a, an active layer 1b, and a second semiconductor layer 1c, which are exposed at side surfaces of the groove. The first electrode 3 is formed on the first semiconductor layer 1a exposed by the insulating pattern 2.

In the general light-emitting element, the insulating pattern 2 may be formed to cover the side surfaces of the groove by taking into account a process margin of the insulating pattern 2. The first electrode 3 may be disposed in a region exposed by the insulating pattern 2. Therefore, in the general light-emitting element, since a width W1 of the first electrode 3 is too narrow, there may be a limitation in increasing a contact area between the first electrode 3 and the first semiconductor layer 1a.

In particular, the general light-emitting element should secure a distance d between the first electrode 3 and the insulating pattern 2.

Specifically, when the distance d between the first electrode 3 and the insulating pattern 2 is insufficient, the first electrode 3 may completely cover the insulating pattern 2 due to the process margin of the first electrode 3. One end of the first electrode 3 may extend to the second semiconductor layer 1c.

In addition, when the distance d between the first electrode 3 and the insulating pattern 2 is insufficient, a reflective layer or the like may not fully fill the distance d between the first electrode 3 and the insulating pattern 2. Accordingly, the second semiconductor layer 1c may be exposed. As a result, a low current failure of the light-emitting element may occur to lower reliability. Therefore, the first electrode 3 and the insulating pattern 2 may have a distance of about 3 μm.

On the contrary, referring again to FIG. 2B, according to an exemplary embodiment of the present invention, since the first electrode 30a is disposed on the bottom surface 20a of the groove 20 and the first insulating pattern 25a is disposed to overlap the first electrode 30a while covering the side surfaces 20b of the groove 20, only a process margin of the first electrode 30a may be considered. That is, the width W2 of the first electrode 30a is wider than that of an existing one, thereby increasing a contact area of the first semiconductor layer 15a.

For example, in the case of FIG. 3, the contact area between the first electrode 3 and the first semiconductor layer 1a is only 2.1% of an area of the light-emitting structure 1. However, in the case of an exemplary embodiment of the present invention, the contact area between the first electrode 30a and the first semiconductor layer 15a may be increased to 3.6% of an area of the light-emitting structure 15, and thus, the contact area between the first electrode 30a and the first semiconductor layer 15a may be increased by 1.5%. Such an increase in the contact area may realize a driving voltage reduction of 0.05 V.

One end of the first insulating pattern 25a according to an exemplary embodiment of the present invention may extend to a portion of the upper surface of the first electrode 30a. That is, since the first insulating pattern 25a completely covers side surfaces of the first electrode 30a, it is possible to prevent the first insulating pattern 25a and the first electrode 30a from being spaced apart from each other and prevent the first semiconductor layer 15a from being exposed in a separated region.

An overlapping distance between one end of the first insulating pattern 25a and the upper surface of the first electrode 30a, i.e., a second distance d2 may be less than 15 μm. This is because when the overlapping distance is too wide, an exposed area of the upper surface of the first electrode 30a is decreased and thus a contact area between the first electrode 30a and a first bonding pad 45a is decreased.

According to the light-emitting element of the exemplary embodiment of the present invention, the first insulating pattern 25a and the first electrode 30a may overlap each other to prevent the first insulating pattern 25a and the edge of the first electrode 30a from being separated from each other. The other end of the first insulating pattern 25a may extend to a portion of the upper surface of the second semiconductor layer 15c.

The first insulating pattern 25a may include an inorganic insulating material having insulating properties, such as SiNx, SiOx, or the like. In addition, the first insulating pattern 25a may include an organic insulating material such as benzocyclobutene (BCB), but the present invention is not limited thereto.

The first reflective layer 40a may be disposed on the second semiconductor layer 15c exposed by the first insulating pattern 25a. The first reflective layer 40a may be made of a material having high reflectivity, such as Ag, Ni, Al, Rh, Pd, Ir, Ru, Mg, Zn, Pt, Au, or Hf. The first reflective layer 40a may be formed by mixing a transparent conductive material such as IZO, IZTO, IAZO, IGZO, IGTO, AZO, or ATO with the material having the high reflectivity.

The above-described first reflective layer 40a may be disposed on an upper portion of the light-emitting structure 15 to reflect light generated in the active layer 15b toward the substrate 10. That is, the first reflective layer 40a may be disposed on a second surface (upper surface) opposite to a first surface (lower surface) of the light-emitting structure 15, through which light is emitted. Thus, the first reflective layer 40a may allow light to be emitted to the outside of the light-emitting element.

A transparent electrode layer 35 may also be disposed between the first reflective layer 40a and the second semiconductor layer 15c. The transparent electrode layer 35 may be made of at least one selected from transparent conductive oxides such as indium tin oxide (ITO), indium zinc oxide (IZO), aluminum zinc oxide (AZO), Aluminum Gallium Zinc Oxide (AGZO), aluminum gallium zinc oxide (IZTO), indium zinc tin oxide (IZTO), indium gallium zinc oxide (IGZO), indium gallium tin oxide (IGTO), antimony tin oxide (ATO), gallium zinc oxide (GZO), IZO nitride (IZON), ZnO, IrOx, RuOx, and NiO.

The transparent electrode layer 35 may improve electrical characteristics of the second semiconductor layer 15c. The transparent electrode layer 35 may be disposed between the second semiconductor layer 15c and the second electrode 30b to perform an ohmic function. The second electrode 30b may be electrically connected to a second bonding pad 45b to prevent a material of the second bonding pad 45b from diffusing into the first reflective layer 40a or the transparent electrode layer 35.

In general, the first reflective layer 40a formed on the transparent electrode layer 35 may have poor contact properties with the first insulating pattern 25a. Therefore, in order to prevent lifting of an interface between the first reflective layer 40a and the first insulating pattern 25a, caused by contact therebetween, the transparent electrode layer 35 may extend to protrude from an edge of the first reflective layer 40a.

As described above, the transparent electrode layer 35 is formed to improve the electrical characteristics of the second semiconductor layer 15c. Desirably, the transparent electrode layer 35 may be formed to completely cover the second semiconductor layer 15c exposed by the first insulating pattern 25a. Since the transparent electrode layer 35 is very thin, when the transparent electrode layer 35 does not extend to an upper surface of the first insulating pattern 25a, it is impossible to verify whether the transparent electrode layer 35 is formed so as to completely cover the upper surface of the second semiconductor layer 15c.

Therefore, an edge of the transparent electrode layer 35 may be formed to overlap the first insulating pattern 25a, thereby grasping whether the transparent electrode layer 35 is properly formed.

When a third distance d3 is too wide, the first insulating pattern 25a and the second reflective layer 40b may be adjacent to each other, and thus, a material of the second reflective layer 40b may be introduced into the first semiconductor layer 15a along the first insulating pattern 25a. Here, the third distance d3 may be an overlapping distance between the transparent electrode layer 35 and the first insulating pattern 25a. On the contrary, when the third distance d3 is too narrow, the transparent electrode layer 35 may not completely cover the second semiconductor layer 15c due to a process margin, and thus, the second semiconductor layer 15c may be exposed. Therefore, the third distance d3 may be in a range of 2 μm to 5 μm.

When a distance between an edge of the first reflective layer 40a and an end of the side surface of the groove 20, i.e., a fourth distance d4 is too narrow, as described above, the first insulating pattern 25a and the second reflective layer 40b may be adjacent to each other, and thus, the material of the second reflective layer 40b may be introduced into the first semiconductor layer 15a along the first insulating pattern 25a. On the contrary, when the fourth distance d4 is too wide, a formed area of the first reflective layer 40a may be narrowed, and thus, reflection efficiency of the first reflective layer 40a may be reduced. Therefore, the fourth distance d4 may be in a range of 10 μm to 15 μm.

The second reflective layer 40b may be disposed to expose only portions of the first electrode 30a and the first reflective layer 40a and to cover an entire surface of the light-emitting structure 15. The second reflective layer 40b may be made of a material which performs both an insulating function and a reflective function. For example, the second reflective layer 40b may include a distributed Bragg reflector (DBR), but the present invention is not limited thereto.

The DBR may have a structure formed by alternately stacking two materials having different refractive indices. The DBR may be formed by repeatedly disposing a first layer having a high refractive index and a second layer having a low refractive index. Both the first and second layers may be dielectric, and the high and low refractive indexes of the first and second layers may be relative refractive indices. Light traveling to the second reflective layer 40b among light emitted from the light-emitting structure 15 may not pass through the second reflective layer 40b due to a refractive index difference between the first layer and the second layer and may be reflected toward the light-emitting structure 15.

One end of the second reflective layer 40b may extend to a portion of the upper surface of the first electrode 30a. The second reflective layer 40b may extend to completely cover an edge of the first insulating pattern 25a.

When the first insulating pattern 25a is exposed in the groove 20, light emitted from the active layer 15b may travel to the upper portion of the light-emitting structure 15 through the first insulating pattern 25a, resulting in a reduction in light emission efficiency. Accordingly, in the light-emitting element according to the exemplary embodiment of the present invention, one end of the second reflective layer 40b extends to a portion of the upper surface of the first electrode 30a so as to completely cover an end of the first insulating pattern 25a.

That is, in the light-emitting element according to the exemplary embodiment of the present invention, the first and second reflective layers 40a and 40b may be disposed on the upper portion of the light-emitting structure 15, thereby efficiently reflecting light generated in the active layer 15b toward the substrate 10.

The second electrode 30b may be disposed on the first reflective layer 40a exposed by the second reflective layer 40b. The second electrode 30b may be made of one selected from Ag, Ni, Al, Rh, Pd, Ir, Ru, Mg, Zn, Pt, Au, Hf, Ti, Cr, Cu, and a selective combination thereof, but the present invention is not limited thereto.

The first bonding pad 45a may be connected to the first electrode 30a exposed by the second reflective layer 40b, and the second bonding pad 45b may be connected to the second electrode 30b exposed by the second reflective layer 40b.

### Second Exemplary Embodiment

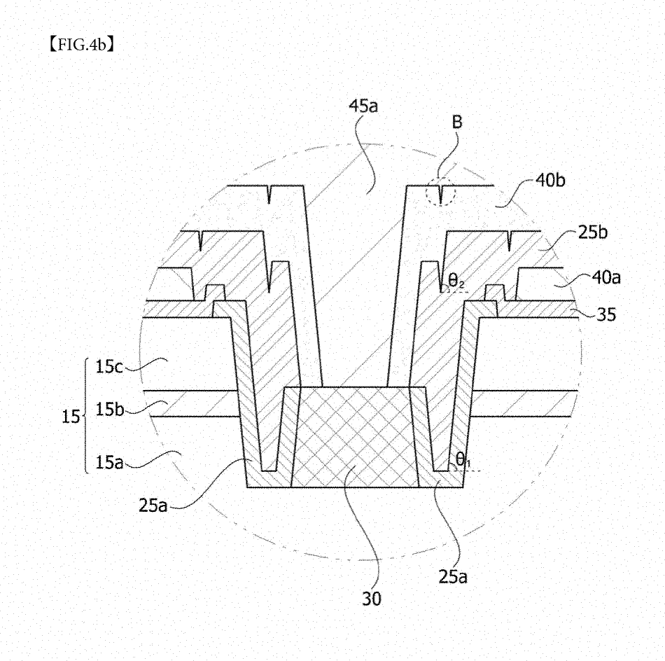

FIG. 4A is a cross-sectional view taken along line I-I′ of FIG. 1, according to another exemplary embodiment, and FIG. 4B is an enlarged view of region A of FIG. 4A.

As shown in FIGS. 4A and 4B, in a light-emitting element of another exemplary embodiment of the present invention, a second insulating pattern 25b may be further formed between the first insulating pattern 25a and the second reflective layer 40b. The second insulating pattern 25b may compensate for a degree of bend is formed in the second reflective layer 40b between the side surface 20b of the groove 20 and the edge of the first electrode 30a.

Specifically, when the groove 20 is too deep, an upper surface of the second reflective layer 40b may not be flat, and a bent portion may be formed between the side surface 20b of the groove 20 and the edge of the first electrode 30a. A thickness of the second reflective layer 40b may not be uniform due to the bent portion, and thus, the second reflective layer 40b may not be partially formed.

However, as in an exemplary embodiment of the present invention, when the second insulating pattern 25b is disposed between the first insulating pattern 25a and the second reflective layer 40b, the second insulating pattern 25b may compensate for a degree of bend is formed in region B of the second reflective layer 40b. In particular, when the second insulating pattern 25b has a sufficient thickness, an upper surface of the second insulating pattern 25b is flat, and a step coverage of the light-emitting element may be improved.

Furthermore, the second insulating pattern 25b may reduce a deviation between coefficients of thermal expansion (CTEs) of the second reflective layer 40b, the light-emitting structure 15, and the first insulating pattern 25a. The second insulating pattern 25b may prevent a surface of the second reflective layer 40b from being lifted or cracked due to a difference between CTEs.

The second insulating pattern 25b may include an inorganic insulating material having insulating properties, such as SiNx, SiOx, or the like. In addition, the second insulating pattern 25b may include an organic insulating material such as benzocyclobutene (BCB), but the present invention is not limited thereto.

Specifically, the first insulating pattern 25a and the second insulating pattern 25b may be formed in a structure which is inclined along the side surface of the groove 20 in a separated region between the edge of the first electrode 30a and the edge of the bottom surface 20a of the groove 20. In this case, a second inclination angle θ2 of an interface between the second insulating pattern 25b and the second reflective layer 40b may be smaller than a first inclination angle θ1 of an interface between the first insulating pattern 25a and the second insulating pattern 25b in a region inclined along the side surface 20b of the groove 20. For example, the first inclination angle θ1 may be in a range of 65° to 70°, and the second inclination angle θ2 may be in a range of 45° to 60°. The second inclination angle θ2 may be decreased as a thickness of the second insulating pattern 25b is increased.

In particular, when an edge of the second insulating pattern 25b completely covers an edge of the first insulating pattern 25a, an exposed area of the upper surface of the first electrode 30a may be reduced by the second insulating pattern 25b. Therefore, it is desirable that the edge of the second insulating pattern 25b matches or exposes the edge of the first insulating pattern 25a. The edge of the second insulating pattern 25b is illustrated in drawings as matching the edge of the first insulating pattern 25a.

The second reflective layer 40b may be formed to completely cover the side surface 20b of the groove 20 in order to prevent light emitted from the active layer 15b from traveling toward first and second bonding pads 45a and 45b through the side surface 20b of the groove 20. The second reflective layer 40b is illustrated in drawings as completely covering the edges of the first and second insulating patterns 25a and 25b.

As described above, in the light-emitting element according to the exemplary embodiments of the present invention, the connection area between the first electrode 30a and the first semiconductor layer 15a may be increased without additionally removing the active layer 15b. Accordingly, a driving voltage may be improved and current spreading of the light-emitting structure 15 may be facilitated. In this case, the second insulating pattern 25b may be disposed between the first insulating pattern 25a and the second reflective layer 40b, thereby compensating for a degree of bend formed in the second reflective layer 40b between the side surface 20b of the groove 20 and the edge of the first electrode 30a. In addition, the second reflective layer 40b may be disposed to cover the side surface 20b of the groove 20 and to easily reflect light traveling to the side surface 20b of the groove 20 toward a light emission surface of the light-emitting structure 15, thereby improving a luminous flux of the light-emitting element.

The light-emitting element according to the exemplary embodiments of the present invention may further include optical members, such as a light guide plate, a prism sheet, and a diffusion sheet, to function as a backlight unit. In addition, the light-emitting element according to the exemplary embodiments may be further applied to a display device, a lighting device, and an indicating device.

Here, the display device may include a bottom cover, a reflective plate, a light-emitting module, a light guide plate, an optical sheet, a display panel, an image signal output circuit, and a color filter. The bottom cover, the reflective plate, the light-emitting module, the light guide plate, and the optical sheet may constitute a backlight unit.

The reflective plate is disposed on the bottom cover, and the light-emitting module emits light. The light guide plate is disposed in front of the reflective plate and guides light emitted from the light-emitting element in a forward direction, and the optical sheet includes a prism sheet and the like and is disposed in front of the light guide plate. The display panel is disposed in front of the optical sheet, the image signal output circuit supplies an image signal to the display panel, and the color filter is disposed in front of the display.

The lighting device may include a substrate, a light source module including the light-emitting element according to the exemplary embodiments, a heat dissipater for dissipating heat of the light source module, and a power supply for processing or converting an electrical signal supplied from the outside and supplying the processed or converted electrical signal to the light source module. In addition, the lighting device may include a lamp, a head lamp, a street lamp, or the like.

The above-described present invention is not limited to the above-described exemplary embodiments and the drawings, and it should be apparent to those skilled in the art that various substitutions, modifications, and variations are possible within a range that does not depart from the technical idea of the exemplary embodiment.

1. A light-emitting element comprising:
a light-emitting structure including a first semiconductor layer, an active layer, and a second semiconductor layer;
a groove configured to expose the first semiconductor layer at a bottom surface thereof and expose the first semiconductor layer, the active layer, and the second semiconductor layer at side surfaces thereof due to the light-emitting structure being removed;
a first electrode connected to the first semiconductor layer exposed at the bottom surface of the groove;
a first insulating pattern configured to cover the first semiconductor layer, the active layer, and the second semiconductor layer which are exposed at the side surfaces of the groove, wherein one end thereof extends to a portion of an upper surface of the first electrode and the other end thereof extends to a portion of an upper surface of the second semiconductor layer such that the upper surfaces of the first electrode and the second semiconductor layer are partially exposed;
a first reflective layer disposed on the exposed second semiconductor layer;
a second reflective layer configured to expose the second semiconductor layer and the first electrode; and
a second electrode disposed on the second semiconductor layer exposed by the second reflective layer.

2. The light-emitting element of claim 1, wherein a distance between an edge of the first electrode and an edge of the bottom surface of the groove is at least 0.05 μm.

3. The light-emitting element of claim 1, wherein an overlapping distance between one end of the first insulating pattern and the upper surface of the first electrode is less than 15 μm.

4. The light-emitting element of claim 1, further comprising a transparent electrode layer disposed between the first reflective layer and the second semiconductor layer.

5. The light-emitting element of claim 4, wherein the transparent electrode layer extends from an edge of the first reflective layer and is exposed on the second semiconductor layer.

6. The light-emitting element of claim 4, wherein one end of the transparent electrode layer extends to an upper surface of the first insulating pattern.

7. The light-emitting element of claim 6, wherein an overlapping distance between the transparent electrode layer and the first insulating pattern is in a range of 2 μm to 5 μm.

8. The light-emitting element of claim 5, wherein a distance between the edge of the first reflective layer and an edge of the groove is in a range of 10 μm to 15 μm.

9. The light-emitting element of claim 1, wherein the second reflective layer is disposed on upper portions of the first reflective layer and the first insulating pattern.

10. The light-emitting element of claim 1, wherein the second reflective layer covers an edge of the first insulating pattern extending to an upper portion of the first electrode.

11. The light-emitting element of claim 1, wherein the first electrode is disposed on the bottom surface.

12. The light-emitting element of claim 1, wherein the first insulating pattern covers the side surfaces of the groove.

13. The light-emitting element of claim 1, wherein the first reflective layer is disposed between the second electrode and the second semiconductor layer.

14. The light-emitting element of claim 1, further comprising a first bonding pad connected to the first electrode exposed by the second reflective layer; and
a second bonding pad connected to the second electrode exposed by the second reflective layer.

15. A light-emitting element comprising:
a light-emitting structure including a first semiconductor layer, an active layer, and a second semiconductor layer;
a groove configured to expose the first semiconductor layer at a bottom surface thereof and expose the first semiconductor layer, the active layer, and the second semiconductor layer at side surfaces thereof due to the light-emitting structure being removed;
a first electrode connected to the first semiconductor layer exposed at the bottom surface of the groove;
a first insulating pattern configured to cover the first semiconductor layer, the active layer, and the second semiconductor layer which are exposed at the side surfaces of the groove, wherein one end thereof extends to a portion of an upper surface of the first electrode and the other end thereof extends to a portion of an upper surface of the second semiconductor layer such that the upper surfaces of the first electrode and the second semiconductor layer are partially exposed;
a first reflective layer disposed on the exposed second semiconductor layer;
a second insulating pattern configured to cover the first reflective layer and expose the second semiconductor layer and the first electrode;
a second reflective layer disposed on the second insulating pattern and configured to expose the second semiconductor layer and the first electrode; and
a second electrode disposed on the second semiconductor layer exposed by the second insulating pattern and the second reflective layer.

16. The light-emitting element of claim 15, wherein the first insulating pattern and the second insulating pattern are formed in a structure which is inclined along the side surface of the groove in a separated region between an edge of the first electrode and an edge of the bottom surface of the groove, and
an inclination angle of an interface between the second insulating pattern and the second reflective layer in a region inclined along the side surface of the groove is smaller than an inclination angle of an interface between the first insulating pattern and the second insulating pattern in a region inclined along the side surface of the groove.

17. The light-emitting element of claim 16, wherein the inclination angle of the interface between the first insulating pattern and the second insulating pattern in the region inclined along the side surface of the groove is in a range of 65° to 70°, and
the inclination angle of the interface between the second insulating pattern and the second reflective layer in the region inclined along the side surface of the groove is in a range of 45° to 60°.

18. The light-emitting element of claim 15, wherein an edge of the second insulating pattern matches an edge of the first insulating pattern extending to an upper portion of the first electrode.

19. The light-emitting element of claim 15, wherein the second reflective layer covers edges of the first insulating pattern and the second insulating pattern.

20. The light-emitting element of claim 15, wherein an edge of the first insulating pattern matches an edge of the second insulating pattern.
